(19) United States
(12) Patent Application Publication
(10) Pub. No.: US 2005/0211987 A1
(43) Pub. Date: Sep. 29, 2005

(54) Semiconductor device, manufacturing method thereof and manufacturing apparatus therefor

(75) Inventors: Ikumi Kashiwagi, Tenri-shi (JP); Junichiro Nakayama, Soraku-gun (JP)

Correspondence Address: EDWARDS & ANGELL, LLP, P.O. BOX 55874, BOSTON, MA, 02205, US

(73) Assignee: Sharp Kabushiki Kaisha

(21) Appl. No.: 11/088,216

(22) Filed: Mar. 22, 2005

(30) Foreign Application Priority Data
Mar. 23, 2004 (JP) 2004-085270(P)

(51) Int. Cl. H01L 29/04; H01L 21/84

(52) U.S. Cl. 257/75; 438/487; 438/149; 117/200

(57) ABSTRACT

A semiconductor device having a semiconductor film formed on a substrate, characterized in that the semiconductor film has laterally grown crystal, and at an end portion of the laterally grown crystal, height of surface projection is lower than film thickness of said semiconductor film, is provided.

This nonprovisional application is based on Japanese Patent Application No. 2004-085270 filed with the Japan Patent Office on Mar. 23, 2004, the entire contents of which are hereby incorporated by reference.

### BACKGROUND OF THE INVENTION

1. Field of the Invention

The present invention relates to a semiconductor device having amorphous semiconductor material crystallized by using a laser, a method of manufacturing the same and an apparatus for manufacturing the same.

2. Description of the Background Art

A thin film transistor (TFT) having a semiconductor device formed on a thin film material is used for a pixel controller and a display portion of an active-matrix liquid crystal display device, and an amorphous material is mainly used as the thin film material. In order to drive TFT at a high speed, a channel region, which had been mainly formed using an amorphous semiconductor film, comes to be crystallized to improve material characteristics. This is because carrier mobility through a crystal, that is, a portion having well-aligned atomic arrangement, becomes hundreds of times larger than through the amorphous portion. In a poly-crystalline structure, however, carriers scatter at grain boundaries. Therefore, larger grain size is desired to realize a single crystal at the channel region.

Though several methods of crystallization have been proposed, methods using a pulse laser have been developed, as these methods allow input of large energy in a short period of time, enabling a low-temperature process. Among these, a method of laterally growing a crystal and a method referred to as Sequential Lateral Solidification (SLS) utilizing the lateral growth have been known.

The crystal formed by the lateral growth method will be described with reference to FIGS. 7A and 7B. FIGS. 7A and 7B are front views of films crystallized by using the lateral growth method. FIG. 7A shows the crystal formed using a narrow mask, and FIG. 7B shows the crystal formed using a wide mask. In the crystal lateral growth method, an amorphous semiconductor film is irradiated with laser beam pulses using a mask, so that the irradiated region is fully melted. The melted semiconductor film is then cooled and re-solidified, and at this time, particular crystallization occurs over a crystal length 71 in a lateral direction, from the vicinity of the boundary of a solid portion that was not melted. When the mask width is rather narrow as shown in FIG. 7A, the lateral crystals collide at a central portion of the pattern, forming projected surface roughness (hereinafter referred to as a “ridge”). This is caused by volume increase that occurs when silicon in liquid phase solidifies, and by the volume increased by solidification, upward projections are formed. When the mask width is considerably wide as shown in FIG. 7B, while lateral crystallization proceeds, the central portion of the pattern starts to cool, so that micro-crystal starts to form from the lower to the upper direction. This hinders lateral crystallization, and thus, a ridge is formed and crystallization stops. The lateral crystal is one large single crystal having the length from the fully melted end to the ridge. When the TFT channel direction is selected to be in this direction of extension, good characteristics can be realized as there is no grain boundary in the direction vertical to the carrier flow.

The SLS method is for making the crystal length longer. As described, for example, in Japanese Patent National Publication No. 2000-505241, lateral crystallization may be continued, using the crystal as a seed. The crystal formed by the SLS method will be described with reference to FIGS. 8A to 8D. FIGS. 8A to 8D are front views of a film crystallized by the SLS method. First, as shown in FIG. 8A, a sample (amorphous semiconductor film) is moved (shifted) by a distance 82 from a rectangular mask or laser and irradiated with laser. Thus, the shifted, laser-irradiated portion 83 is fully melted and re-solidified. Here, as the crystal grains formed in the last stage are taken over as seeds, as shown in FIG. 8B, a large single crystal having the length of 81+82 can be obtained. Further, by repeating the shift and laser irradiation as shown in FIGS. 8C and 8D, a single crystal having a desired length can be obtained.

In this process, by shifting the sample by an appropriate amount, the ridge about to be formed in lateral crystallization can be eliminated. When a region that covers the generated ridge is irradiated with laser for the next stage, the region is again fully melted and the ridge disappears. A new ridge is formed at a position extended by lateral growth of crystal. Thus, in the final crystal region where the TFT channel portion will be formed, the projected surface roughness (surface projection height) referred to as a ridge does not exist, and a flat surface can be obtained.

Even in the SLS method, however, the ridge still remains in the last region of repeated laser irradiation, which poses a problem in the subsequent process of device manufacturing. By way of example, when a film for a gate portion, contact portion or the like is deposited on that region of the semiconductor film which includes the ridge, film thickness will be uneven. Further, film thickness sufficient to cover the ridge is necessary, which imposes a limitation in device design and, in addition, degradation in characteristics is highly possible. This is also a disadvantage for further miniaturization in the future.

In Japanese Patent National Publication No. 2003-509845, in order to reduce the height of ridge at the last region of SLS method, modulation of laser beam intensity using an attenuator has been proposed. According to this proposal, the semiconductor film is melted partially, so that lateral crystallization does not occur, and as a result, the ridge can be eliminated. For this approach, however, new equipments including an attenuator and a system for driving the attenuator are necessary. In a production system of which laser irradiation frequency is high, the attenuator and the like must be operated at high speed, and thus, implementation thereof is difficult.

The present invention was made to solve the above-described problems, and its object is to provide a method of manufacturing a semiconductor device, a manufacturing apparatus and a semiconductor device manufactured by the method and apparatus, that can reduce the height of surface projection (ridge) in the last region of repetitive laser irradiation in the SLS method.

### SUMMARY OF THE INVENTION

The present invention provides a semiconductor device having a semiconductor film formed on a substrate, characterized in that the semiconductor film has laterally grown crystal, and at an end portion of the laterally grown crystal, height of surface projection is lower than film thickness of the semiconductor film.

Preferably, the laterally grown crystal is formed by irradiating the semiconductor film with laser.

Preferably, the laterally grown crystal has crystal growth enlarged by moving stepwise the laser irradiation along a surface direction of the semiconductor film to be continuous from a portion of crystal grown laterally by the laser irradiation, so that the crystal at the portion is turned over.

Preferably, the height of surface projection at the end portion of the laterally grown crystal is made lower than film thickness of the semiconductor film by using laser having energy lower than the laser used for forming the laterally grown crystal.

Preferably, a laser having energy lower than the laser used for forming the laterally grown crystal is used in the last step of the stepwise laser irradiation of the semiconductor device.

Preferably, a laser having energy lower than the laser used for forming the laterally grown crystal is used in last few steps of the stepwise laser irradiation of the semiconductor device.

Preferably, a laser having energy lower than the laser used for forming the laterally grown crystal is used at a position of last irradiation of the stepwise laser irradiation of the semiconductor device.

The present invention also provides a method of manufacturing a semiconductor device having a semiconductor film formed on a substrate, including the steps of: laterally growing crystal in the semiconductor film by irradiating the semiconductor film with laser; and lowering a height of surface projection at an end portion of the laterally grown crystal to be lower than the thickness of the semiconductor film, by irradiating laser having energy lower than the laser used for forming the laterally grown crystal.

Preferably, laser irradiation for laterally growing crystal in the semiconductor film is moved stepwise to take over a portion of grown crystal.

Preferably, the laser having energy lower than the laser used for forming the laterally grown crystal is used in the last step of the stepwise laser irradiation.

Preferably, the laser having energy lower than the laser used for forming the laterally grown crystal is used in last few steps of the stepwise laser irradiation of the semiconductor device.

Preferably, the laser having energy lower than the laser used for forming the laterally grown crystal is used at a position of last irradiation of the stepwise laser irradiation of the semiconductor device.

Preferably, amount of energy irradiation is adjusted by moving a position of a lens or a stage, to realize irradiation of laser having energy lower than the laser used for forming the laterally grown crystal.

Preferably, one of two laser oscillators having the same wavelength is stopped to realize irradiation of laser having energy lower than the laser used for forming the laterally grown crystal.

Preferably, in stepwise laser irradiation for laterally growing crystal in the semiconductor film, a main laser oscillator having a wavelength easily absorbed in the semiconductor film and a sub laser oscillator having a wavelength easily absorbed in the substrate or the semiconductor film in a melted state are used, and the sub laser oscillator is stopped to realize irradiation of laser having an energy lower than the laser used for forming the laterally grown crystal.

The present invention further provides an apparatus for manufacturing a semiconductor device, used for a method of manufacturing any of the semiconductor devices described above, including first and second laser oscillators, and a controller for controlling these two oscillators.

Preferably, energy of laser emitted from the second laser oscillator is lower than energy of laser emitted from the first laser oscillator.

Preferably, the laser emitted from the first laser oscillator has a wavelength easily absorbed in the semiconductor film, and the laser emitted from the second laser oscillator has a wavelength easily absorbed in the substrate or the semiconductor film in a melted state.

Preferably, one of the two laser oscillators is stopped to make height of surface projection at an end portion of laterally grown crystal lower than the thickness of the semiconductor film.

Preferably, the laser oscillator that is stopped is the second laser oscillator.

By the semiconductor device manufacturing method and the manufacturing apparatus of the present invention, a semiconductor device can be provided, in which the height of surface projection at an end portion of crystallization is made lower than the film thickness of the semiconductor film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of the semiconductor device in accordance with the present invention.

FIGS. 2A to 2C schematically show vertical sections of the semiconductor device formed by the method of manufacturing a semiconductor device in accordance with the present invention and the conventional method.

FIG. 3 is a schematic illustration of a general apparatus for crystallizing a semiconductor film.

FIG. 4 is a schematic illustration of an apparatus that can be used for manufacturing the semiconductor device of the present invention.

FIG. 5 is a schematic illustration of another apparatus that can be used for manufacturing the semiconductor device of the present invention.

FIG. 6 is a graph schematically representing the relation between first and second laser beam irradiation times and outputs (emission intensity).

FIG. 7A is a front view of a film crystallized by lateral growth method of crystal, using a narrow mask.

FIG. 7B is a front view of a film crystallized by lateral growth method of crystal, using a wide mask.

FIG. 8A to 8D are front views of a film crystallized by the SLS method.

### DESCRIPTION OF THE PREFERRED EMBODIMENTS

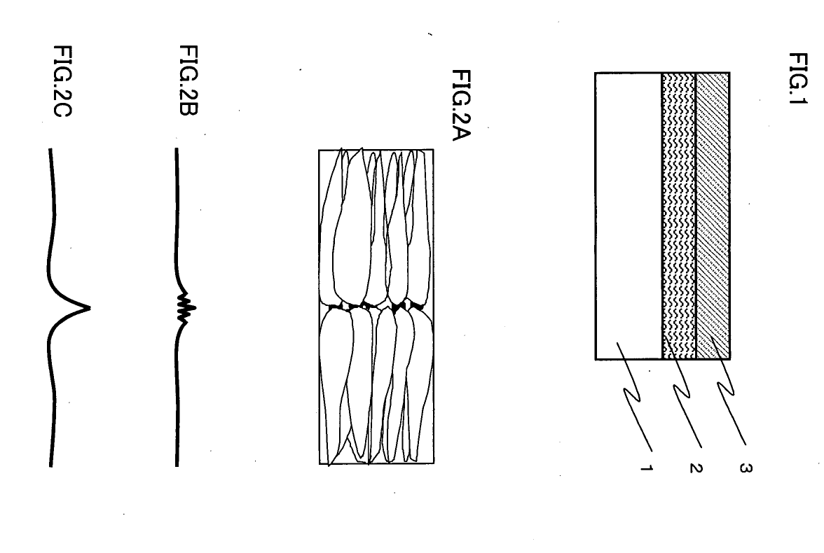

The semiconductor device of the present invention will be described with reference to FIG. 1. FIG. I is a schematic sectional view of the semiconductor device in accordance with the present invention. As can be seen from FIG. 1, the structure includes a substrate 1, an underlying insulating film 2 and an amorphous semiconductor film 3 formed thereon. Preferably, substrate 1 is of an insulating material, and a glass substrate or a quartz substrate may be used. Use of a glass substrate is suitable, as it is inexpensive and allows easy manufacturing of a substrate having a large area.

For underlying insulating film 2, a silicon nitride film, a silicon oxynitride film, or a silicon oxide film may be used. Preferable film thickness is 50 nm to 200 nm, but not limited thereto. Underlying insulating film 2 may be formed by plasma enhanced chemical vapor deposition (PECVD), vapor deposition, or sputtering of the material mentioned above.

Semiconductor film 3 is deposited to the thickness of 10 nm to 100 nm, by plasma enhanced chemical vapor deposition (PECVD), Catalytic Chemical Vapor Deposition (Cat-CVD), vapor deposition or sputtering. Any conventionally known material having semiconductor characteristic may be used for semiconductor film 3, and amorphous silicon, various characteristics of which can be significantly improved when length of crystal growth is made longer, is a preferred material of the film. The material is not limited to amorphous such as amorphous silicon, and semiconductor film 3 before crystallization by laser irradiation may be crystalline, such as micro-crystalline or poly-crystalline semiconductor film. The material of semiconductor film 3 is not limited to one consisting solely of silicon, but may be a material mainly consisting of silicon and including other element such as germanium.

The present invention provides a technique for crystallizing the semiconductor film, particularly to form single crystal, in the semiconductor device having such a structure as described above. Specifically, the present invention provides a technique for making the height of surface projection lower than the film thickness of the semiconductor film at the time of crystallization. The present invention is characterized in that it includes the steps of irradiating the semiconductor film with a laser beam to cause lateral crystal growth of the semiconductor film, and irradiating with laser beam having lower energy than that used for lateral crystal growth to make the height of surface projection at an end portion of said lateral crystal growth lower than the film thickness of the semiconductor film.

In the present invention, lateral growth of crystal is possible by irradiating the semiconductor film with a laser beam by the SLS method, as described above. Here, the lateral direction refers to the direction that is substantially parallel to the surface of the semiconductor film. Specifically, crystal growth of a semiconductor film occurs mainly in the surface direction and the thickness direction of the semiconductor film, and the lateral direction corresponds to the direction along the surface. Further, in order to realize growth of a single crystal in the lateral direction, lateral crystal growth attained by one laser pulse is taken over by the next laser pulse irradiation, and the thus attained crystal growth is further taken over by the next laser pulse irradiation. In the present invention, such a manner of laser irradiation for continuous crystal growth will be referred to as stepwise laser irradiation. By such a stepwise laser irradiation, the form of crystal generated by the first laser irradiation can be taken over, and therefore, one crystal, or single crystal can be formed. Further, the ridge generated by immediately preceding laser pulse irradiation can also be eliminated by the next laser pulse irradiation.

When crystal growth proceeds in the lateral direction in such a manner, surface projection of a certain height results at the terminal end of crystal growth, as described above. The present invention is characterized in that the height of the surface projection as such can be made lower than the film thickness of the semiconductor film. In order to lower the height of surface projection, the present invention uses means for emitting laser having lower energy than that of the laser used for lateral crystal growth. Preferably, the laser with lower energy may be used in the last step, or in the last few steps, of the stepwise laser irradiation. Further, preferably, the laser is directed to that position of the semiconductor film which is to be irradiated last. As the semiconductor film is irradiated with laser having lower energy, it is not fully melted in the thickness direction but only the upper portion of the film is melted. Then, larger number of crystal nuclei generate at the solid/liquid interface, and micro-crystal grows in the film from the lower portion to the surface. As re-crystallization takes place in a mechanism different from that of lateral growth, the height of surface projection can sufficiently be lowered. As will be described later, advantage of using laser having large absorption coefficient in a semiconductor film is further utilized. The laser irradiation in last few steps may preferably be started from the second or third shot, but not limited thereto, and appropriate design should be made to attain the object that the height of surface projection is made lower than the film thickness using laser with lower energy together. If the laser energy in the last irradiation were not sufficiently low, the semiconductor film would be fully melted, forming the ridge again. On the contrary, if the laser energy were too low, the ridge of the semiconductor film could not be melted. Namely, by designing the process such that the laser energy is gradually reduced in several steps, the height of surface projection can surely be reduced.

In the present invention, the laser beam used in the method of manufacturing the semiconductor device desirably has large absorption coefficient in the semiconductor film, so as to prevent any influence on the substrate. More specifically, the laser beam used in the method of manufacturing the semiconductor device desirably has a wavelength in ultra-violet region. One example is excimer laser pulse having the wavelength of 308 nm. Further, preferably, the laser beam used in the method of manufacturing the semiconductor device has such an amount of energy per unit irradiation area that can melt the semiconductor film in a solid state by one irradiation, that is, an amount of energy sufficient to heat the semiconductor film in its entire thickness to a temperature higher than the melting point. The amount of energy varies dependent on the material type of semiconductor film, thickness of the semiconductor film, area of the region to be crystallized and so on, and cannot be determined uniquely. Therefore, it is desirable to use laser beam of appropriate energy amount as needed.

In the present invention, the method of crystallization is in accordance with the SLS method described in connection with the prior art. As described above, amorphous silicon is used as semiconductor film 3 shown in FIG. 1, of which thickness is about 50 nm. In this case, the amount of energy of excimer laser necessary for the SLS method is 2 to 8 kJ/m². It is noted, however, that in the last laser irradiation, the laser energy is reduced so as to not fully melt the silicon film, and the silicon film is partially melted. Specifically, by the second last irradiation immediately before the last irradiation, the entire region to be crystallized is irradiated with laser. At this time, a ridge is formed by the second last irradiation. Therefore, the silicon film having the thus formed ridge is partially melted only in the vicinity of the film surface by the last irradiation, and re-crystallized in the direction from the interface to the solid portion toward the surface of the film. The amount of energy of the excimer laser for the last irradiation is 1 to 4 kJ/m², that is, about one half the energy necessary for the crystal growth.

FIGS. 2A to 2C are schematic views of the crystals of semiconductor films formed in accordance with the method of manufacturing a semiconductor device of the present invention and the conventional method. FIG. 2A is a front view of the semiconductor film formed by the manufacturing method of the present invention, FIG. 2B is a sectional view of the crystal film of FIG. 2A formed by the manufacturing method of the present invention, and FIG. 2C is a sectional view of the crystal film formed by the conventional method. Assuming that the semiconductor film thickness of FIG. 2A is 50 nm, the height of surface projection in FIG. 2B is 30 nm, while the height of surface projection in FIG. 2C is 50 nm. Therefore, the height of surface projection could be reduced from 50 nm of the prior art to 30 nm, which is smaller than the thickness of the semiconductor film.

(Apparatus)

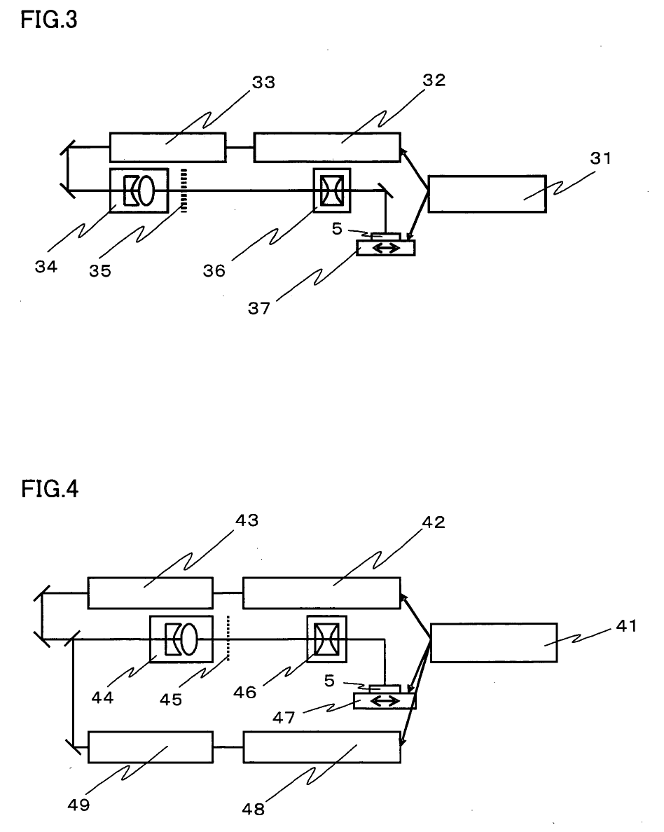

A general apparatus used for crystallizing a deposited semiconductor film will be described with reference to FIG. 3. FIG. 3 is a schematic diagram of the apparatus for crystallizing semiconductor film 3 such as shown in FIG. 1, which includes a laser oscillator 32, a variable attenuator 33, a field lens 34, a mask 35, an imaging lens 36, a sample stage 37 and a number of mirrors. These components are controlled by a controller 31. By using the laser processing apparatus, irradiation pulses can be supplied to a semiconductor device 5 on stage 37. By moving the position of the imaging lens along the direction of optical axis by using these components, the degree of focusing on the semiconductor film can be adjusted and the laser energy can be attenuated. Alternatively, similar effects can be attained by changing the position of the sample stage in the up/down direction.

FIG. 4 shows an apparatus that can be used for manufacturing the semiconductor device of the present invention. The laser apparatus of the present invention is capable of crystallizing a deposited semiconductor film, and includes, as shown in FIG. 4, first and second excimer laser oscillators 42 and 48. The apparatus further includes variable attenuators 43, 49, a field lens 44, a mask 45, an imaging lens 46, a sample stage 47 and a number of mirrors. The two oscillators 42 and 48 are controlled by a controller 41. By time-synchronized oscillation, the power of each of the oscillators can be reduced to about one-half, or by offset in time, the time period in which the semiconductor film melts can be elongated, so that the length of crystal grain can be made longer. In the example described above, amorphous silicon of 50 nm is used as the semiconductor film, and the amount of energy per unit irradiation area of each excimer laser oscillator necessary for the SLS method is 1 to 4 kJ/m².

The method of crystallization in accordance with the SLS method is as described above. In last step or last few steps of laser irradiation, the first or second excimer laser oscillator 42 or 48 is stopped, so that the semiconductor film is partially melted and the height of surface projection is reduced. Further, laser beam may be irradiated a number of times at the same position, without moving the sample stage.

As compared with the example using the apparatus described previously, the irradiation energy is reduced by stopping oscillation, and therefore, the ridge height can be advantageously reduced without lowering the throughput.

Another apparatus for manufacturing the semiconductor device of the present invention will be described with reference to FIG. 5. The semiconductor device and the method of manufacturing are the same as described above, and therefore, description thereof will not be repeated.

As shown in FIG. 5, another laser apparatus for crystallizing the deposited semiconductor film of the present invention is characterized in that it includes first and second laser oscillators 52 and 58. Components denoted by reference numbers same in the first digit as those of FIG. 4 are the same as described above, and therefore, description thereof will not be repeated. Different from the apparatus of FIG. 4, this apparatus uses a combination of a second laser having a wavelength different from that of the first laser. Specifically, the second laser is used as an assisting laser, for suppressing temperature decrease of the melted semiconductor film, whereby the time until the melted semiconductor film re-solidifies can be made longer. Thus, the grain size of the generated crystal in the lateral direction can significantly be enlarged.

Here, preferably, the first laser beam used in the method of manufacturing a semiconductor device of the present invention has a wavelength of higher coefficient of absorption to the semiconductor film in the solid state than the second laser beam. Specifically, it may preferably have the wavelength in the ultra-violet region. More specifically, as mentioned above, an example of the first laser beam is an excimer laser pulse having the wavelength of 308 nm.

Further, preferably, the second laser beam used in the method of manufacturing a semiconductor device of the present invention has a wavelength of higher coefficient of absorption to the semiconductor film in the liquid state or to the underlying insulating film than the first laser beam. Specifically, it may preferably have the wavelength in the visible to infrared region. More specifically, examples of the second laser beam used in the method of manufacturing a semiconductor device of the present invention include YAG laser having the wavelength of 532 nm, YAG laser having the wavelength of 1064 nm and carbon dioxide gas laser having the wavelength of 10.6 μm. The first and second laser beams refer to the laser beams emitted from the first and second laser oscillators, respectively.

Preferably, the total energy of the first and second laser beams used in the method of manufacturing a semiconductor device of the present invention is sufficient to melt the semiconductor film in the solid state per unit area in one irradiation. Alternatively, such a setting is also possible that the first laser beam used in the method of manufacturing a semiconductor device of the present invention has an amount of energy sufficient to melt the semiconductor film in the solid state per unit area in one irradiation, and the second laser beam used in the method of manufacturing a semiconductor device of the present invention has an amount of energy less than necessary to melt the semiconductor film in the solid state per unit area in one irradiation. These amounts of energy vary dependent on the material type of semiconductor film, thickness of the semiconductor film, area of the region to be crystallized and so on, and cannot be determined uniquely. Therefore, it is desirable to use laser beams of appropriate energy amounts as needed, in accordance with the manner of implementation of the method of manufacturing a semiconductor device of the present invention. By way of example, if amorphous silicon of 50 nm is used as the semiconductor film, the amount of energy of the first laser necessary for the SLS method is 1 to 4 kJ/m², and the amount of energy of the second laser is 1 to 4 kJ/m².

(Laser Irradiation Intensity)

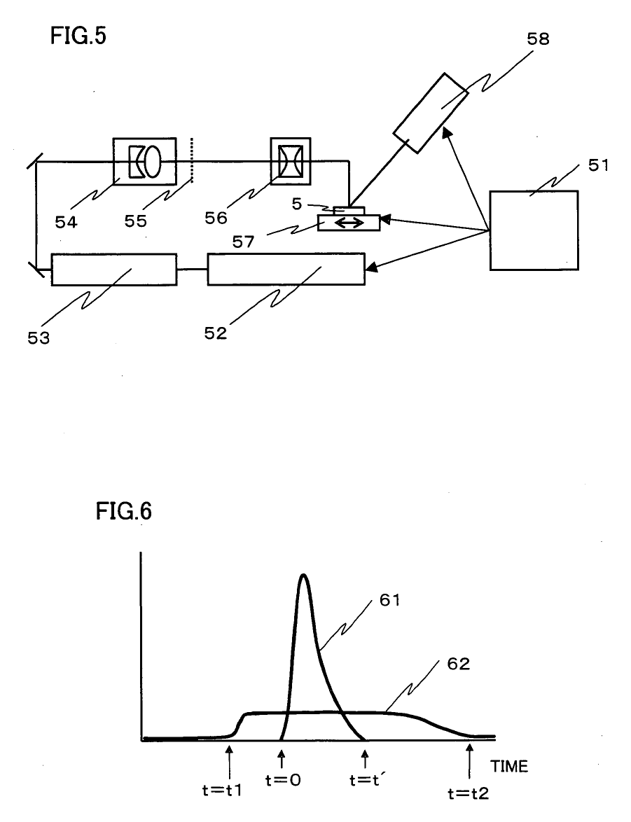

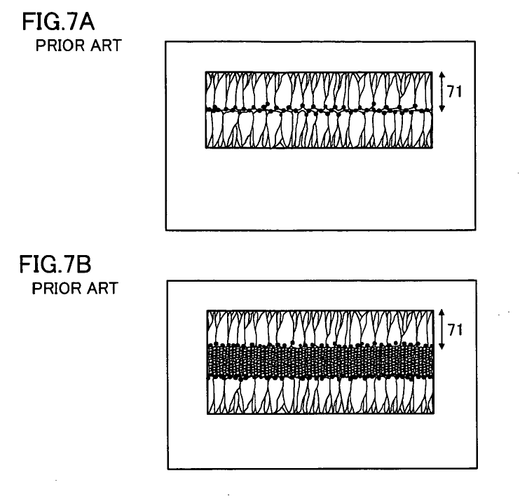

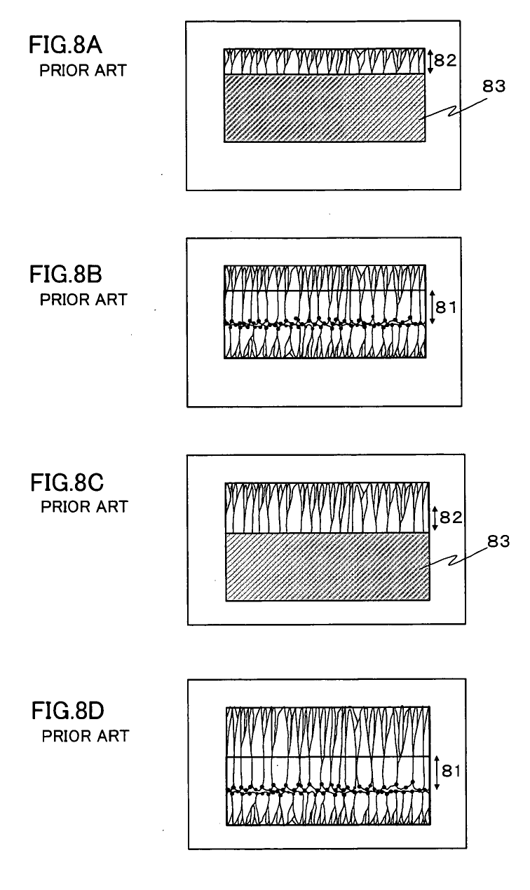

FIG. 6 is a graph schematically representing a relation between irradiation time of the first and second laser beams and the output (irradiation intensity). Here, the abscissa represents time (time point), and the ordinate represents output (unit: W/m²). The first laser beam is plotted by line 61, and the second laser beam is plotted by line 62. Emission of the first laser beam is set to start at time t=0, and to attain the output of 0 at t=t′. The second laser beam is emitted with high output between t1 and t2, while kept at a low output in other periods. Here, t1<t2. The relation between the irradiation time of the first and second laser beams and the output is not limited to the one shown here, and the time t1 may be of a positive or negative value. Specifically, it may be before or after the start of irradiation of the first laser beam. By appropriately setting t2, the time until the melted semiconductor film re-solidifies can be elongated, and the grain size of the generated crystal in the lateral direction can significantly be enlarged. Preferably, t′<t2. Further, preferably, t1<t′.

As described above, the method of crystallization is the SLS method described in connection with the prior art. It is noted, however, that in the last laser irradiation, the second laser as the assisting laser is stopped, to cause partial melting of the silicon film. Here, even if irradiation frequency is high, what is done is simply to stop laser without using any attenuator, and therefore, ridge height can be reduced without lowering the throughput.

Further, it is also possible to stop the second laser for the last few irradiations. Alternatively, at a position for the last laser irradiation, irradiation with only the first laser may be performed a number of times, without moving the sample stage. Such operation can further and surely reduce the height of the surface projection.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device having a semiconductor film formed on a substrate, characterized in that the semiconductor film has laterally grown crystal, and at an end portion of the laterally grown crystal, height of surface projection is lower than film thickness of said semiconductor film.

2. The semiconductor device according to claim 1, wherein
said laterally grown crystal is formed by irradiating said semiconductor film with laser.

3. The semiconductor device according to claim 1, wherein
said laterally grown crystal has crystal growth enlarged by moving stepwise said laser irradiation along a surface direction of the semiconductor film to be continuous from a portion of crystal grown laterally by the laser irradiation, so that the crystal at said portion is turned over.

4. The semiconductor device according to claim 2, wherein
the height of surface projection at the end portion of the laterally grown crystal is made lower than film thickness of the semiconductor film by using laser having energy lower than said laser used for forming said laterally grown crystal.

5. The semiconductor device according to claim 3, wherein
a laser having energy lower than said laser used for forming said laterally grown crystal is used in the last step of the stepwise laser irradiation of said semiconductor device.

6. The semiconductor device according to claim 3, wherein
a laser having energy lower than said laser used for forming said laterally grown crystal is used in last few steps of the stepwise laser irradiation of said semiconductor device.

7. The semiconductor device according to claim 3, wherein
a laser having energy lower than said laser used for forming said laterally grown crystal is used at a position of last irradiation of the stepwise laser irradiation of said semiconductor device.

8. A method of manufacturing a semiconductor device having a semiconductor film formed on a substrate, comprising the steps of:
laterally growing crystal in said semiconductor film by irradiating said semiconductor film with laser; and
lowering a height of surface projection at an end portion of said laterally grown crystal to be lower than thickness of said semiconductor film, by irradiating laser having an energy lower than said laser used for forming said laterally grown crystal.

9. The method of manufacturing a semiconductor device according to claim 8, wherein
laser irradiation for laterally growing crystal in said semiconductor film is moved stepwise to take over a portion of grown crystal.

10. The method of manufacturing a semiconductor device according to claim 9, wherein
the laser having energy lower than said laser used for forming said laterally grown crystal is used in the last step of the stepwise laser irradiation.

11. The method of manufacturing a semiconductor device according to claim 9, wherein
the laser having energy lower than said laser used for forming said laterally grown crystal is used in last few steps of the stepwise laser irradiation of said semiconductor device.

12. The method of manufacturing a semiconductor device according to claim 9, wherein
the laser having energy lower than said laser used for forming said laterally grown crystal is used at a position of last irradiation of the stepwise laser irradiation of said semiconductor device.

13. The method of manufacturing a semiconductor device according to claim 8, wherein
amount of energy irradiation is adjusted by moving a position of a lens or a stage, to realize irradiation of laser having energy lower than said laser used for forming said laterally grown crystal.

14. The method of manufacturing a semiconductor device according to claim 8, wherein
one of two laser oscillators having the same wavelength is stopped to realize irradiation of laser having energy lower than said laser used for forming said laterally grown crystal.

15. The method of manufacturing a semiconductor device according to claim 9, wherein
in stepwise laser irradiation for laterally growing crystal in said semiconductor film, a main laser oscillator having a wavelength easily absorbed in the semiconductor film and a sub laser oscillator having a wavelength easily absorbed in the substrate or the semiconductor film in a melted state are used, and said sub laser oscillator is stopped to realize irradiation of laser having an energy lower than said laser used for forming said laterally grown crystal.

16. An apparatus for manufacturing a semiconductor device, used for a method of manufacturing the semiconductor device according to claim 1, comprising
first and second laser oscillators, and a controller for controlling these two oscillators.

17. The apparatus for manufacturing a semiconductor device according to claim 16, wherein ‘energy of laser emitted from the second laser oscillator is lower than energy of laser emitted from the first laser oscillator.

18. The apparatus for manufacturing a semiconductor device according to claim 16, wherein
the laser emitted from the first laser oscillator has a wavelength easily absorbed in the semiconductor film, and the laser emitted from the second laser oscillator has a wavelength easily absorbed in the substrate or the semiconductor film in a melted state.

19. The apparatus for manufacturing a semiconductor device according to claim 16, wherein
one of said two laser oscillators is stopped to make height of surface projection at an end portion of laterally grown crystal lower than thickness of the semiconductor film.

20. The apparatus for manufacturing a semiconductor device according to claim 19, wherein
said laser oscillator that is stopped is the second laser oscillator.
